(19) United States
(12) Patent Application Publication
(10) Pub. No.: US 2023/0213568 A1
(43) Pub. Date: Jul. 6, 2023

(54) Trailer Testing Device

(71) Applicant: Jonathan P. Hobbs, Indianapolis, IN (US)

(72) Inventor: Jonathan P. Hobbs, Indianapolis, IN (US)

(21) Appl. No.: 17/567,220

(22) Filed: Jan. 3, 2022

(51) Int. Cl. G01R 31/00; B60T 17/22; B60Q 1/30

(52) U.S. Cl. CPC G01R 31/006; B60Q 1/305; B60T 17/22

(57) ABSTRACT

The present disclosure relates generally to measuring and testing circuits of towed vehicles. Testing circuits of towed vehicles for proper function is required for safe use of the vehicle. Instruments that currently exist are expensive, the instruments are large in size, use outdated technology to perform the test and do not provide a means to reliably and effectively test braking systems.

### BACKGROUND

### Field of the Invention

The following disclosure relates generally to a method and device that provides electrical signals to a towed vehicle for the purpose of measuring and testing electrical circuits of a towed vehicle.

### Description of the Related Art

The present disclosure relates generally to measuring and testing circuits of towed vehicles. Testing circuits of towed vehicles for proper function is required for safe use of the vehicle. Instruments that currently exist are expensive, the instruments are large in size, use outdated technology to perform the test and do not provide a means to reliably and effectively test braking systems.

### SUMMARY

The novel technology relating to measuring and testing circuits of towed vehicles is set forth, in the claims below, and the following is not in any way to limit, define or otherwise establish the scope of legal protection.

One object of the novel technology is to provide improved testing of the towed vehicle.

Towed vehicles are used to transport goods, materials, and practically any object to be transported from one place to another. Proper function of circuits of the towed vehicle and the towed vehicle braking system is critical for the safe use of the towed vehicle.

These circuits can only be partially tested by the operator with the powered vehicle electrically connected to the towed vehicle. For example, the operator can power the light circuits, commonly known as marker lights, of the towed vehicle to check for proper operation but cannot observe the brake light circuit operation without assistance actuating the brake pedal.

Furthermore, the electrical circuit that controls the actuation of the brakes cannot be tested. In order to test the operation of the electrical circuits of the brakes the operator must attach the powered vehicle and drive it with the attached vehicle to test how the vehicle stops. This test provides no accurate measurement of brake circuits and the operator must rely on instinct and experience to judge the operation. This disclosure provides a solution to this problem.

Brake circuits of towed vehicles have operational characteristics that can be defined by a voltage and amperage of the brake circuit. Towed vehicles commonly have drum brakes that are actuated by magnets. The total amperage and voltage required to operate drum brakes is a unique number, and would be dependent on the size and length of the wiring and the number of axles having drum brakes. A deviation from this unique number would indicate a problem with the operation of the drum brakes alerting the operator that a problem exists.

Towed vehicles with air brakes have similar electrical characteristics. Air brakes operate by applying a voltage to an air solenoid circuit. The applied voltage actuates the solenoid releasing the pressure of the brake pad on the brake. The air solenoid circuit has unique voltage and amperage characteristics that when measured can aid the operator in detecting abnormalities in the braking system of the tractor trailer.

Testing of a towed vehicle by an operator with a towing vehicle is inefficient for a number of reasons. For example, if the towed vehicle circuits are faulty the operator will be delayed in transporting the goods. In the case where the operator finds the fault, the operator may not be qualified to repair the fault. In both cases shipment of the goods can be delayed. This disclosure provides a solution to this problem by allowing testing to be performed at any time, by any person, at any time without a towing vehicle.

In the case where a technician is testing the circuits of the towed vehicle or a fleet of towed vehicles, the technician must move a vehicle to each towed vehicle, attach it, and move the towed vehicle to test all the circuits. This is very inefficient as it takes time and fuel to move the towed vehicles. The disclosed technology provides a method and a device for testing circuits of a towed vehicle that is efficient, cost-effective, simple to use, and has a minimal form factor.

Further objects, embodiments, forms, benefits, aspects, features and advantages of the described technology may be obtained from the description, drawings, and claims provided herein.

### BRIEF DESCRIPTION OF THE DRAWINGS

The accompanying drawings, which are included to provide a further understanding of the invention are incorporated in and constitute a part of this specification, illustrate an embodiment of the invention and together with the description serve to explain the principles of the invention. They are meant to be exemplary illustrations provided to enable persons skilled in the art to practice the disclosure and are not intended to limit the scope of the appended claims.

FIG. 1 is a perspective view of the testing device according to one example of the novel technology.

FIG. 2 is a perspective view of the testing device according to one example of the novel technology.

FIG. 3 is a perspective view of the testing device according to one example of the novel technology.

FIG. 4 is a view of the testing device according to one example of the novel technology.

FIG. 5 is a view of the testing device in use according to one example of the novel technology.

FIG. 6 is a schematic view of the testing device according to one example of the novel technology.

FIG. 7 is a schematic view of the testing device according to one example of the novel technology.

### DETAILED DESCRIPTION

For the purposes of promoting an understanding of the principles of the described technology and presenting its currently understood best mode of operation, reference will now be made to the embodiments illustrated in the drawings and specific language will be used to describe the same. It will nevertheless be understood that no limitation of the scope of the described technology is thereby intended, with such alterations and further modifications in the illustrated device and such further applications of the principles of the described technology as illustrated therein being contemplated as would normally occur to one skilled in the art to which the described technology relates.

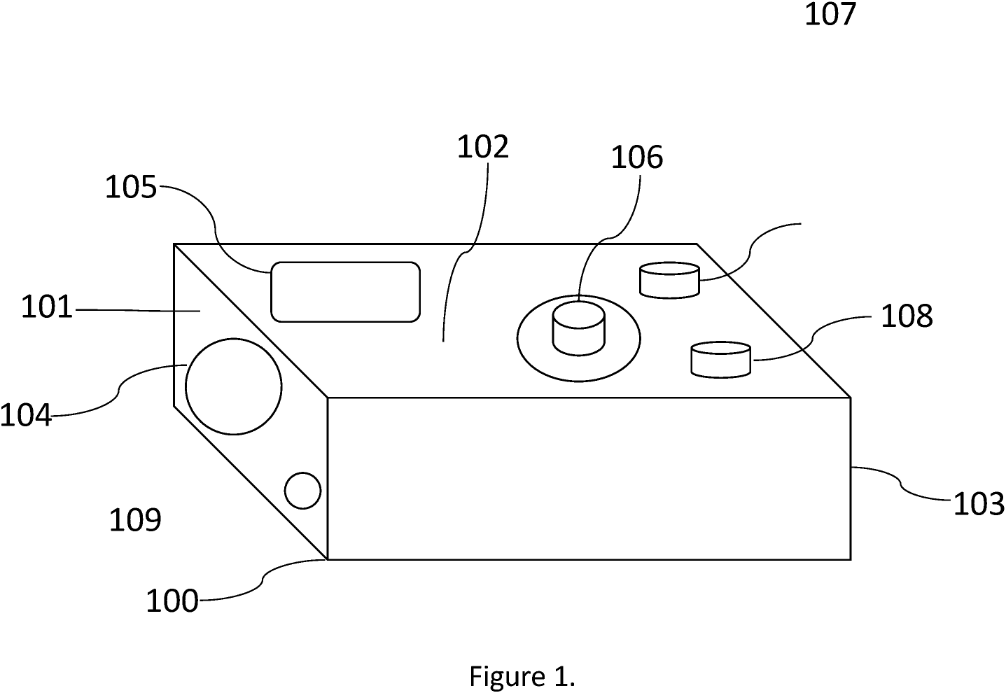

Detailed reference will be made to one or more embodiments of the disclosure which are described in FIGS. 1 through 7.

FIG. 1 shows a perspective view of a testing device 100 according to one example of the novel technology. The testing device 100 is configured for use with a trailer 220 but not limited to the trailer 220. The testing device 100 is suitable for use with any towed vehicle, examples of towed vehicles include recreational vehicles, tractor trailers, car dollys and the like.

The specification and claims of the disclosure will describe the operation of the testing device 100 on the trailer 220. Port 104 of the testing device 100 is configured to be connected to trailer port 200 of the trailer 220. One skilled in the art will recognize that the invention described in this disclosure can be configured to operate on any type of trailer, tractor trailer, recreational vehicle or 5^{th} wheel without any undue experimentation.

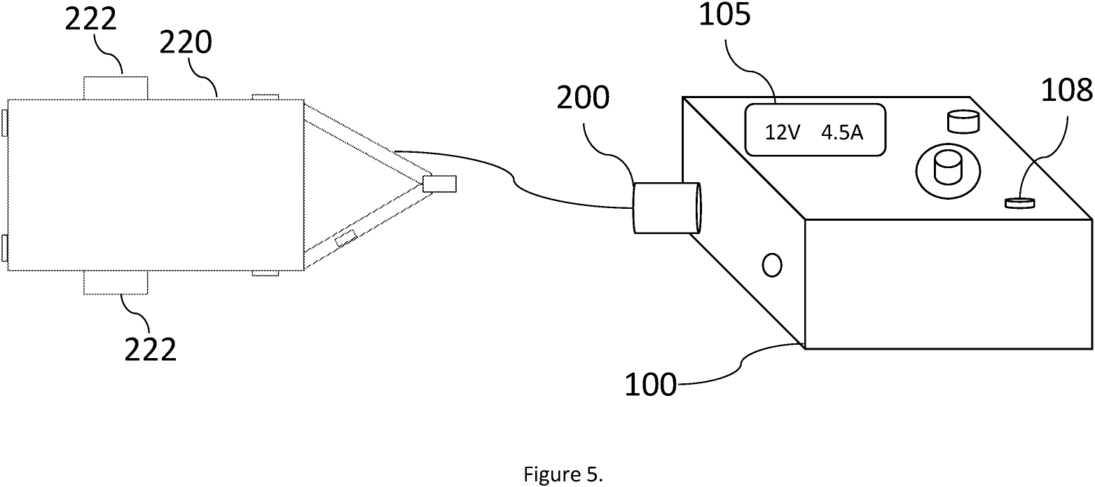

The trailer 220 shown in FIG. 5 is configured with a plurality of lights 221, a plurality of brakes 222, auxiliary power/charging 223 and a port 200 for connecting to a vehicle that supplies electrical power and a plurality of signals to the trailer 220.

The testing device 100 comprises a housing 102 and a testing circuit 300. The housing 102 houses the testing circuit 300. The testing device 100 provides electrical power to the trailer 220 through the trailer port 200 enabling testing of the plurality of lights 221, the brakes 222, and the auxiliary power/charging 223. The testing device 100 allows testing of the circuits of the trailer 220 in the absence of a power source.

The testing device 100 shown in FIG. 1 is configured with a power switch 107, a momentary switch 108, a rotary switch 106, a meter display 105, a port 104 and a charging port 109 on a side 101 in this example. The power switch 107 in this example is a single pole single throw switch. The momentary switch 108 is a normally off single pole pressure operated switch in this example. The rotary switch 107 is a single pole 6-way rotary switch in this example. The meter display 105 is a meter configured to display amperage of a circuit. The meter display 105 is not limited to only displaying amperage and can also be configured to display voltage. The port 104 is configured to electrically connect to the trailer port 200 of the trailer 220, the port 104 is not limited to this configuration and can be configured in a plurality of configurations.

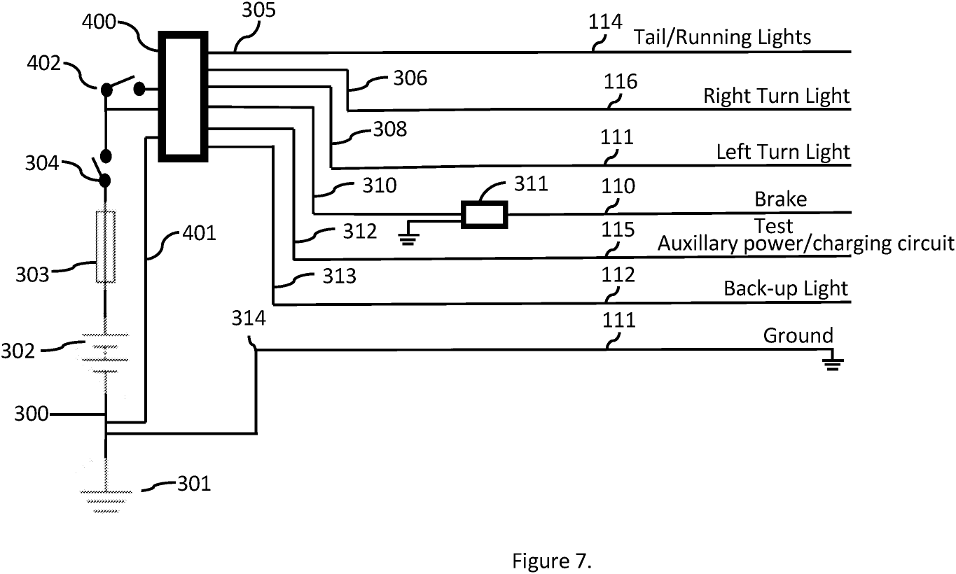

The testing device 100 in FIG. 1 is configured with a rotary switch 106 in this example allowing manual switching. In one prospective embodiment of the testing device 100 which will be described later in the disclosure, switching is performed automatically by a microprocessor 400 shown in FIG. 7.

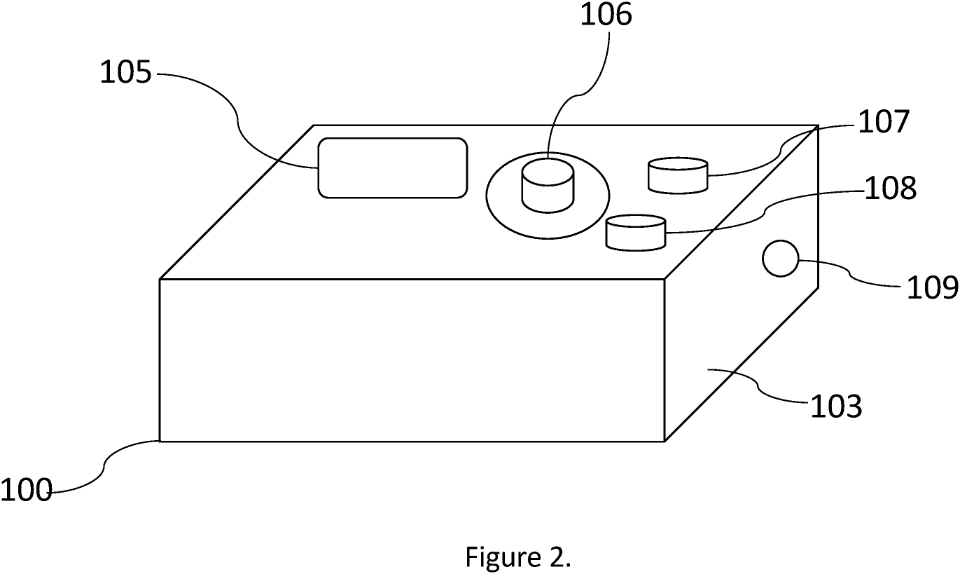

FIG. 2 shows an example of the testing device 100 having a side 103 wherein the charging port 109 is positioned on the opposing end of the testing device 100. The positioning of the port 103 and the charging port 109 is not limited to the configuration shown in FIG. 1 and FIG. 2 and can be configured in a plurality of configurations.

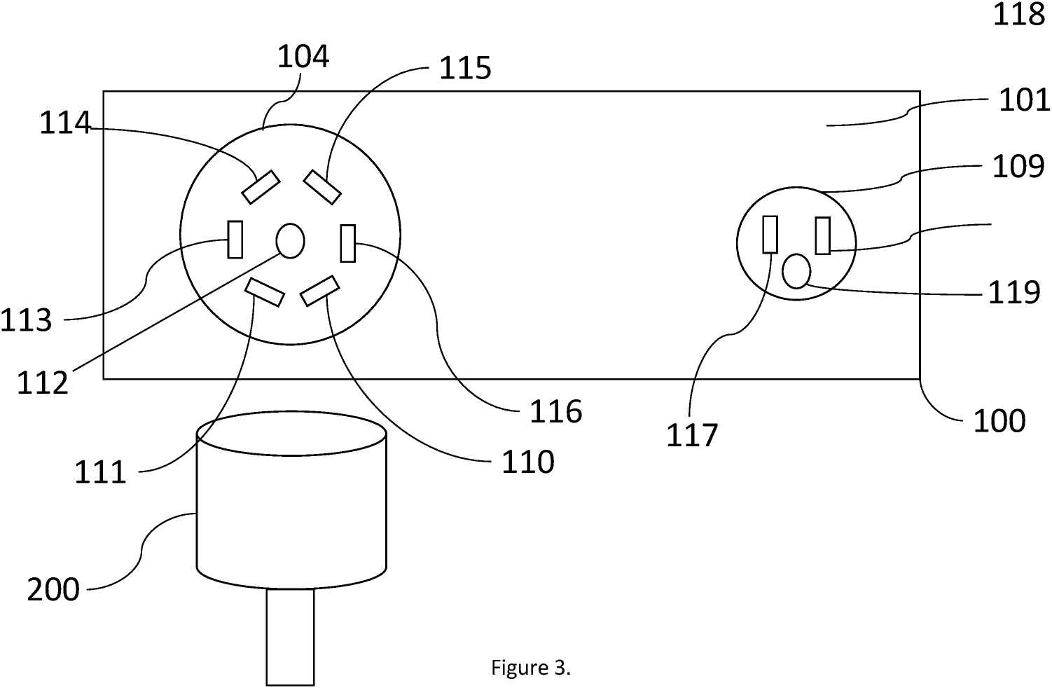

FIG. 3 shows a side view 101 of the testing device 100 of this example. Port 104 and the charging port 109 are respectively configured on the side view 101 of the testing device 100 in this example. Port 104 is configured to electrically connect pin 114 to pin 201 of trailer port 200. Port 104 is further configured to electrically connect pin 113 to pin 202 of trailer port 200, pin 111 to pin 204 of trailer port 200, pin 110 to pin 205 of trailer port 200, pin 116 to pin 206 of trailer port 200, pin 115 to pin 207 of trailer port 200 in this example. The charging port 109 is configured to electrically connect pin 118 to a positive voltage pin 117 to a neutral voltage and pin 119 to a ground in this example.

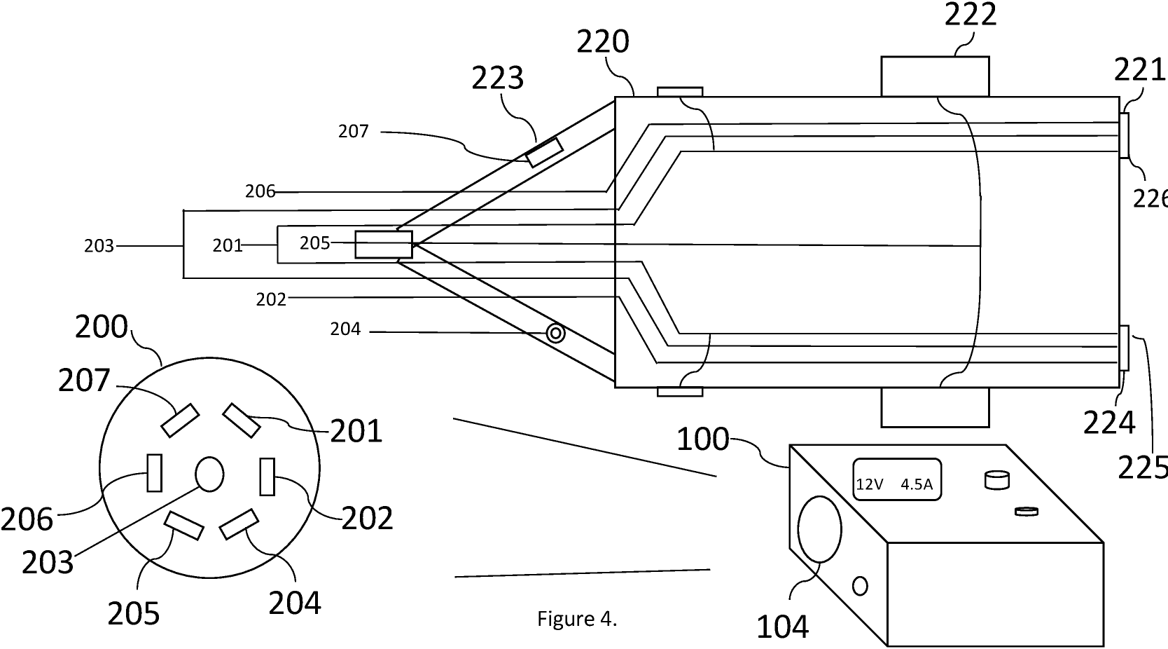

FIG. 4 shows a view of the trailer 220 the trailer port 200 and the testing device 100. The trailer 220 is configured with a plurality of tail/running lights 221. The trailer 220 is further configured with brakes 222, an auxiliary power/charging 223, back-up lights 224, left turn/stop indicator lights 225, right turn/stop indicator lights 226, frame ground 204. Pin 201 of trailer port 200 is configured to electrically connect to the plurality of tail/running lights 221 of the trailer 220. Pin 202 of trailer port 200 is configured to electrically connect to the left turn/stop indicator lights 225 of the trailer 220. Pin 204 of trailer port 200 is configured to electrically connect to the frame ground 204 of the trailer 220. Pin 205 of trailer port 200 is configured to electrically connect to the brakes 222 of the trailer 220. Pin 206 of trailer port 200 is configured to electrically connect to the right turn/stop indicator lights 226 of the trailer 220. Pin 207 of trailer port 200 is configured to electrically connect to the auxiliary power/charging 223 of the trailer 220. Pin 203 of trailer port 200 is configured to electrically connect to the back-up lights 224 of the trailer 220. Trailer port 200 of the trailer 220 is configured to electrically connect to port 104 of the testing device 100.

FIG. 5 shows an example of a brake test being performed on the trailer 220 with the testing device 100. The trailer port 200 of the trailer 220 is connected to the testing device 100. The meter display 105 in this example displays a voltage and amperage. Actuating the momentary switch 108 in this example supplies power to the brakes 222. The meter display 105 displays the measured voltage and amperage characteristics of the circuit for the brakes 222 in this example.

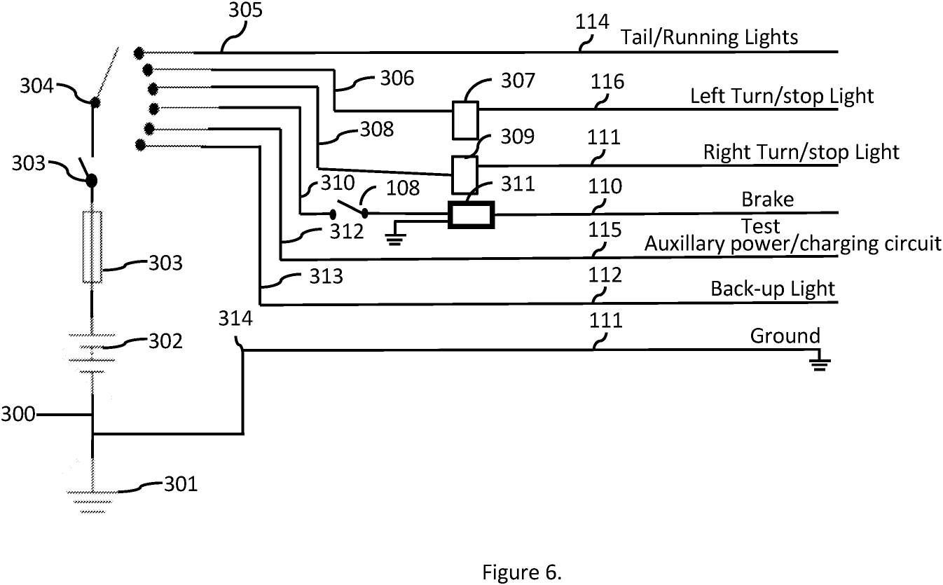

FIG. 6 shows the circuit 300 housed in the testing device 100. The circuit 300 is configured with a power source 302 electrically connected to a ground 301. The power source 302 is electrically connected to the circuit 300 through a fused connector 303. The circuit 300 is configured with a switch 303 that allows electrical power to flow from the power source 302. The circuit 300 is further configured with a 6-way rotary switch 304, a first intermittent flashing relay 307 a second intermittent flashing relay 309, and a meter 311. The operation of circuit 300 will be described in the following paragraph.

Closing the switch 303 allows electrical power to flow to the rotary switch 304 in this example. The rotary switch 304 in a first position 305 allows electrical power to flow to pin 114 of the port 104. Pin 114 of port 104 is electrically connected to the plurality of tail/running lights 221 of the trailer 220. The rotary switch 304 in a second position 306 allows electrical power to flow to the first intermittent flashing relay 307. The first intermittent flashing relay 307 allowing electrical power to flow to pin 116 of the port 104 intermittently, pin 116 electrically connected to the left turn/stop indicator light 225.

The rotary switch 304 in a third position 308 allows electrical power to flow to the second intermittent flashing relay 309. The second intermittent flashing relay 309 allowing electrical power to flow to pin 111 of the port 104 intermittently pin 111 electrically connected to the right turn/stop indicator light 226. The rotary switch 304 in a fourth position 310 allows electrical power to flow to the momentary switch 108. Actuating the momentary switch 108 allows electrical power to flow to the meter 311. Electrical power flows through meter 311 to pin 110 of the port 104. The meter 105 configured to measure the electrical power flowing to pin 110 of port 104. Pin 110 of port 104 is electrically connected to the brakes 222.

The rotary switch 304 in a fifth position 312 allows electrical power to flow to pin 115 of the port 104. Pin 115 of port 104 electrically connected to the auxiliary power/charging 223 circuit. The rotary switch 304 in a sixth position 313 allows electrical power to flow to pin 112 of the port 104. Pin 112 of port 104 electrically connected to the back-up lights 224 of the trailer 220. The circuit 300 further configured with a ground 314 electrically connected to pin 111 of the port 104. Pin 111 of port 104 connected to pin 205 of trailer port 200 to the frame ground 204 of the trailer 220.

FIG. 7 shows a prospective embodiment of the disclosure wherein a microprocessor 400 is configured to switch circuits instead of the rotary switch 106. In the prospective embodiment, the circuit 300 is configured with a power source 302 electrically connected to a ground 301. The power source 302 electrically connected to the circuit 300 through a fused connector 303. The circuit 300 is configured with a switch 303 that allows electrical power to flow from the power source 302. The circuit 300 is further configured with a start switch 402, and a meter 311.

The switch 304 electrically connects the microprocessor to the power source 302. A second ground 401 electrically connects the microprocessor 400 to ground 301.

The microprocessor 400 is programmed to send electrical power to each circuit of the trailer 220. The electrical power sent to each circuit may be pulse wave modulated, commonly known as PWM or sustained electrical power. The duration of the electrical power sent to each circuit being no less than 3 seconds and not exceeding 120 seconds.

Activating the start switch 402 signals the microprocessor 400 to send a first PWM of electrical power to a first output 305. The first output 305 allows electrical power to flow to pin 114 of the port 104. Pin 114 of port 104 is electrically connected to the plurality of tail/running lights 221 of the trailer 220. Actuating the start switch 402 resets the testing device 100 off and on again resets the test.

The microprocessor 400 is further programmed to send an intermittent second PWM of electrical power to a second output 306. The second output 306 allows electrical power to flow to pin 116 of the port 104. Pin 116 of port 104 electrically connected to the left turn/stop indicator lights 225 of the trailer 220.

The microprocessor 400 is further programmed to send an intermittent third PWM of electrical power to a third output 308. The third output 308 allows electrical power to flow to pin 111 of the port 104. Pin 111 of port 104 is electrically connected to the right turn/stop indicator lights 226 of the trailer 220.

The microprocessor 400 is further programmed to send a fourth signal of sustained PWM electrical power to a fourth output 310 for a period of seconds. The fourth output 310 allows electrical power to flow to the meter 311. Electrical power flows through meter 311 to pin 110 of the port 104. The meter 311 is configured to measure the electrical power flowing to pin 110 of port 104. Pin 110 of port 104 is electrically connected to the brakes 222.

The microprocessor 400 is further programmed to send a fifth PWM of electrical power to a fifth output 312. The fifth output 312 allows electrical power to flow to pin 115 of the port 104. Pin 115 of port 104 electrically connected to the auxiliary power/charging 223 circuit.

The microprocessor 400 is further programmed to send a sixth PWM of electrical power to a sixth output 313. The sixth output 313 allows electrical power to flow to pin 112 of the port 104. Pin 112 of port 104 electrically connected to the back-up lights 224 of the trailer 220.

While the described technology has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the described technology are desired to be protected.

The inventor claims:

1. A testing device comprising:
wherein the testing device comprises a housing and a testing circuit;
wherein the housing contains the testing circuit;
wherein the testing device is configured to test a trailer;
wherein the trailer comprises a trailer port, a plurality of lights, a power source, and brakes;
wherein the trailer port connects the plurality of lights, power source, and brakes to a vehicle electric power system;
wherein the vehicle electric power system provides control signals and electric power to the plurality of lights, power source, and the brakes;
wherein the testing device connects to the trailer port through a port;
wherein the testing device provides electric power to the plurality of lights, the power source, and the brakes;
wherein the testing circuit comprises a power source, a fused connector, a switch, a rotary switch, a first intermittent flashing relay, a second intermittent flashing relay, a momentary switch and a meter;
wherein the trailer port comprises a tail/running light pin, a left turn/stop pin, a right turn/stop pin, a brake pin, an auxiliary power/charging pin, a back-up light pin, and a ground pin;
wherein the testing device port comprises a tail/running light pin, a left turn/stop pin, a right turn/stop pin, a brake pin, an auxiliary power/charging pin, a back-up light pin, and a ground pin;
wherein the trailer port and the testing device port connect to form an electrical connection between the testing device and the trailer;
wherein the testing circuit power source positive terminal electrically connects to the fused connector with a first lead, a second lead connects the fused connector to the switch, a third lead connects the switch to the rotary switch;
wherein a first switching position of the rotary switch electrically connects the third lead to the tail/running light of the trailer;
wherein a second switching position of the rotary switch electrically connects the third lead to the first intermittent flashing relay, the first intermittent flashing relay electrically connected to the left turn/stop light of the trailer;
wherein a third switching position of the rotary switch electrically connects the third lead to the second intermittent flashing relay, the second intermittent flashing relay electrically connected to the right turn/stop light of the trailer;
wherein a fourth switching position of the rotary switch electrically connects the third lead to the momentary switch, the momentary switch electrically connected to the meter and the brakes of the trailer;
wherein a fifth switching position of the rotary switch electrically connects the third lead to the auxiliary power/charging circuit of the trailer;
wherein a sixth switching position of the rotary switch electrically connects the third lead to the back-up light of the trailer;
wherein the negative lead of the power source electrically connects the ground terminal of the trailer;
wherein the meter measures the electrical power characteristics of the brakes.

2. The testing device according to claim 1
wherein a microprocessor performs the switching of the rotary switch;
wherein the testing circuit comprises a power source, a fused connector, a switch, a start switch, and a meter;
wherein the testing circuit power source positive terminal electrically connects to the fused connector with a first lead, a second lead connects the fused connector to the switch, a third lead connects the switch to the microprocessor a fourth lead connects the switch to the start switch, a fifth lead connects the start switch to an input pin on the microprocessor, a sixth lead connects the microprocessor power circuit to ground;
wherein a first output lead of the microprocessor electrically connects to the tail/running light of the trailer;
wherein a second output lead of the microprocessor electrically connects to the left turn/stop light of the trailer;
wherein a third output lead of the microprocessor electrically connects to the right turn/stop light of the trailer;
wherein a fourth output lead of the microprocessor electrically connects to the meter and the brakes of the trailer;
wherein a fifth output lead of the microprocessor electrically connects to the auxiliary power/charging circuit of the trailer;
wherein a sixth output lead of the microprocessor electrically connects to the back-up light of the trailer;
wherein the negative lead of the power source electrically connects the ground terminal of the trailer;
wherein the microprocessor is programmed to send electrical power to each circuit of the trailer;
wherein the electrical power is pulse wave modulated;
wherein the duration of the pulse wave modulated electrical power sent to each circuit is between 3 and 120 seconds.

3. The testing device according to claim 1
wherein the power source is a rechargeable lithium ion battery;
wherein the switch is a normally open single pole two position switch;
wherein the rotary switch is a single pole six position switch;
wherein the first intermittent flashing relay is a turn signal flashing relay;
wherein a second intermittent flashing relay is a turn signal flashing relay;
wherein the momentary switch is a normally open single pole switch;
wherein the meter is an electrical power sensing meter capable of displaying the amp draw of the brakes;
wherein the meter is an electrical power sensing meter capable of displaying the voltage supplied to the brakes.

4. The testing device according to claim 2
wherein the power source is a rechargeable lithium ion battery;
wherein the switch is a normally open single pole two position switch;
wherein the start switch is a normally open single pole switch;
wherein the meter is an electrical power sensing meter capable of displaying the amp draw of the brakes;
wherein the meter is an electrical power sensing meter capable of displaying the voltage supplied to the brakes.
